(19) United States
(12) Patent Application Publication
(10) Pub. No.: US 2025/0194433 A1
(43) Pub. Date: Jun. 12, 2025

(54) SEMICONDUCTOR DEVICE INCLUDING MAGNETIC TUNNEL JUNCTION STRUCTURES AND METHOD OF FABRICATING THE SAME

(71) Applicant: SK hynix Inc., Icheon-si (KR)

(72) Inventor: Jong Min YUN, Icheon-si (KR)

(21) Appl. No.: 18/892,238

(22) Filed: Sep. 20, 2024

(30) Foreign Application Priority Data
Dec. 12, 2023 (KR) 10-2023-0179282

(51) Int. Cl. H10N 50/80; H10B 61/00; H10N 50/01; H10N 50/10

(52) U.S. Cl. CPC H10N 50/80; H10B 61/00; H10N 50/01; H10N 50/10

(57) ABSTRACT

A semiconductor device includes first magnetic tunnel junction structures arranged in first and second directions crossing each other and having a first width in the first direction; second magnetic tunnel junction structures arranged in the first direction and the second direction and arranged alternately with the first magnetic tunnel junction structures in a third direction crossing the first and second directions, and having a second width of the first direction greater than the first width; and third magnetic tunnel junction structures having a long axis parallel to the first direction and a short axis parallel to the second direction, arranged alternately with the first magnetic tunnel junction structures in the first direction, and arranged alternately with the second magnetic tunnel junction structures in the second direction, and having the long axis parallel to the second direction and the short axis parallel to the first direction.

### CROSS-REFERENCE TO RELATED APPLICATIONS

The patent document claims the priority and benefits of Korean Patent Application No. 10-2023-0179282, filed on Dec. 12, 2023, which is incorporated herein by reference in its entirety.

### TECHNICAL FIELD

The technology disclosed in this patent document relates to a semiconductor technology, and more particularly, to a semiconductor device including magnetic tunnel junction structures, and a method of fabricating the semiconductor device.

### BACKGROUND

With the recent trend toward miniaturization, low-power consumption, and high performance in the electrical and electronics industry, the importance of semiconductor devices that may store data in various electronic devices, such as computers and portable communication devices, is increasing. Such semiconductor devices include semiconductor memory devices that may store data by using the characteristic of switching between different resistance states according to the applied voltage or current, for example, a resistive random access memory (RRAM), a phase-change random access memory (PRAM), a ferroelectric random access memory (FRAM), a magnetic random access memory (MRAM), and electronic fuse (E-fuse).

### SUMMARY

The disclosed technology can be implemented in some embodiments to provide a semiconductor device that includes magnetic tunnel junction structures of varied sizes that may be easily formed, and a method for fabricating the same.

In an embodiment of the disclosed technology, a semiconductor device includes: a plurality of first magnetic tunnel junction structures that are arranged in a first direction and a second direction intersecting with each other and having a first width in the first direction; a plurality of second magnetic tunnel junction structures that are arranged in the first direction and the second direction and arranged alternately with the first magnetic tunnel junction structures in a third direction intersecting with the first and second directions, and having a second width of the first direction which is greater than the first width; and third magnetic tunnel junction structures having a long axis parallel to the first direction and a short axis parallel to the second direction, arranged alternately with the first magnetic tunnel junction structures in the first direction, and arranged alternately with the second magnetic tunnel junction structures in the second direction, and having the long axis parallel to the second direction and the short axis parallel to the first direction, arranged alternately with the second magnetic tunnel junction structures in the first direction, and arranged alternately with the first magnetic tunnel junction structures in the second direction.

In another embodiment of the disclosed technology, a method for fabricating a semiconductor device includes: forming a magnetic tunnel junction layer over a substrate; forming a sacrificial layer over the magnetic tunnel junction layer; forming a plurality of first spacer patterns extending in a second direction and having different distances from each other in a first direction over the sacrificial layer; forming a material layer that covers the first spacer pattern; forming a plurality of second spacer patterns extending in the first direction and having different distances from each other in the second direction over the material layer; etching the material layer by using the second spacer pattern while maintaining the first spacer pattern to expose a portion of the sacrificial layer that does not overlap with the first and second spacer patterns; forming a space by etching the exposed portion of the sacrificial layer; forming a hard mask pattern to fill the space; removing the sacrificial layer; and etching the magnetic tunnel junction layer by using the hard mask pattern as an etch barrier to form a plurality of magnetic tunnel junction structures having different widths.

In another embodiment of the disclosed technology, a semiconductor device may include a plurality of first magnetic tunnel junction structures arranged in a first direction and a second direction intersecting with each other and having a first width in the first direction, a plurality of second magnetic tunnel junction structures arranged in the first direction and the second direction and arranged alternately with the first magnetic tunnel junction structures in a third direction intersecting with the first and second directions, and having a second width in the first direction, wherein the second width is greater than the first width, and a plurality of third magnetic tunnel junction structures, a first group of third magnetic tunnel junction structures having a third width in the first direction and a fourth width in the second direction, arranged alternately with the first magnetic tunnel junction structures in the first direction, and arranged alternately with the second magnetic tunnel junction structures in the second direction, a second group of third magnetic tunnel junction structures having a fifth width in the second direction and a sixth width in the first direction, arranged alternately with the second magnetic tunnel junction structures in the first direction, and arranged alternately with the first magnetic tunnel junction structures in the second direction, wherein the third width is greater than the fourth width, and the fifth width is greater than the sixth width.

In another embodiment of the disclosed technology, a method for fabricating a semiconductor device may include forming a magnetic tunnel junction layer over a substrate, forming a sacrificial layer over the magnetic tunnel junction layer, forming a plurality of first spacer patterns extending in a second direction and having different intervals from each other in a first direction over the sacrificial layer, forming a material layer that covers the first spacer pattern, forming a plurality of second spacer patterns extending in the first direction and having different intervals from each other in the second direction over the material layer, etching the material layer by using the second spacer pattern as an etch mask while maintaining the first spacer pattern to expose a portion of the sacrificial layer that does not overlap with the first and second spacer patterns, forming a space by etching the exposed portion of the sacrificial layer, forming a hard mask pattern to fill the space, removing the sacrificial layer, and etching the magnetic tunnel junction layer by using the hard mask pattern as an etch barrier to form a plurality of magnetic tunnel junction structures having different widths.

### BRIEF DESCRIPTION OF THE DRAWINGS

FIGS. 1A and 1B illustrate a semiconductor device based on an embodiment of the disclosed technology.

FIG. 2 is a cross-sectional view illustrating an example of a magnetic tunnel junction structure.

FIGS. 3A to 3B illustrate a method for fabricating a semiconductor device based on an embodiment of the disclosed technology.

FIGS. 4A to 4B illustrate a method for fabricating a semiconductor device based on an embodiment of the disclosed technology.

FIGS. 5A to 5B illustrate a method for fabricating a semiconductor device based on an embodiment of the disclosed technology.

FIGS. 6A to 6B illustrate a method for fabricating a semiconductor device based on an embodiment of the disclosed technology.

FIGS. 7A to 7B illustrate a method for fabricating a semiconductor device based on an embodiment of the disclosed technology.

FIGS. 8A and 8B illustrate a semiconductor device based on another embodiment of the disclosed technology.

FIGS. 9A and 9B illustrate a semiconductor device based on another embodiment of the disclosed technology.

### DETAILED DESCRIPTION

Embodiments of the disclosed technology will be described below in more detail with reference to the accompanying drawings.

Hereinafter, the various embodiments of the disclosed technology will be described in detail with reference to the attached drawings.

The drawings are not necessarily to scale and, in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

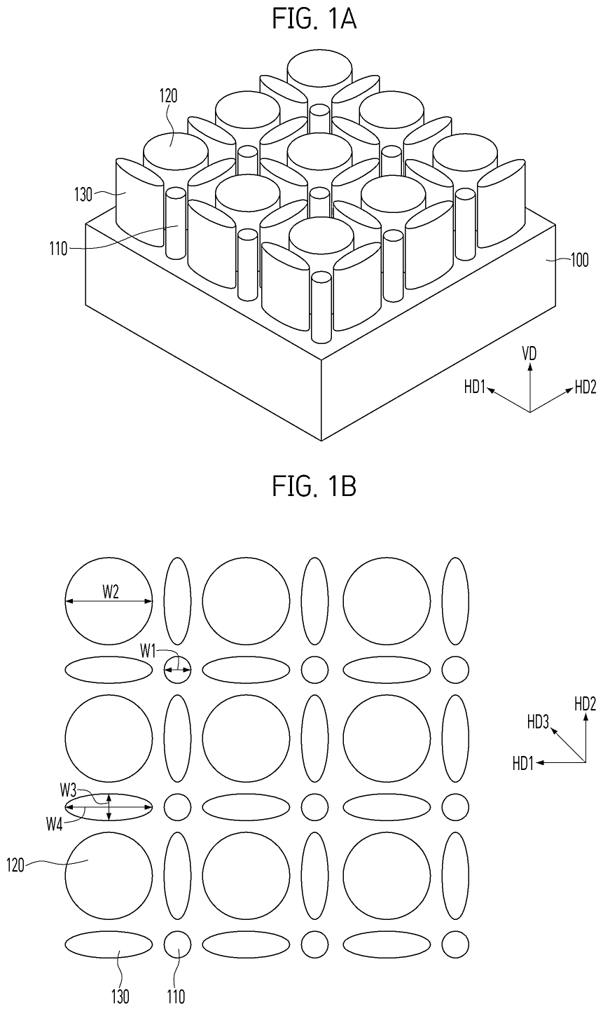

FIGS. 1A and 1B illustrate a semiconductor device in accordance with an embodiment of the disclosed technology. FIG. 1A is a perspective view, and FIG. 1B is a top view of FIG. 1A.

Referring to FIGS. 1A and 1B, the semiconductor device based on an embodiment of the disclosed technology may include a substrate 100, and first magnetic tunnel junction structures 110, second magnetic tunnel junction structures 120, and third magnetic tunnel junction structures 130 that are disposed over the substrate 100.

The substrate 100 may include a semiconductor material, such as silicon or another suitable substrate material. In an embodiment, the substrate may include an insulating material layer such as a silicon oxide layer or a silicon nitride layer. Also, a certain lower structure (not shown) may be formed in or otherwise supported by the substrate 100. For example, conductive lines may be formed in or over the substrate 100 or otherwise supported by the substrate 100 to be electrically connected to the first magnetic tunnel junction structure 110 and/or the second magnetic tunnel junction structure 120, or an integrated circuit for driving the conductive lines.

The first magnetic tunnel junction structure 110 may have a pillar shape. In an embodiment, the first magnetic tunnel junction pattern 110 may have a circular shape or a shape similar to the circular shape in a top view. The first magnetic tunnel junction structures 110 may be arranged in a matrix form in a first horizontal direction HD1 and a second horizontal direction HD2 that are substantially parallel to a surface of the substrate 100. The first horizontal direction HD1 and the second horizontal direction HD2 may be substantially perpendicular to each other. Also, a direction substantially perpendicular to the surface of the substrate 100 will be referred to as a vertical direction VD. A width of the first magnetic tunnel junction structure 110 in the first horizontal direction HD1 or the second horizontal direction HD2 (e.g., diameter) will be hereinafter referred to as a first width W1.

The second magnetic tunnel junction structure 120 may have a pillar shape. In an embodiment, the second magnetic tunnel junction pattern 120 may have a circular shape or a shape similar to the circular shape in a top view. The second magnetic tunnel junction structures 120 may be arranged in a matrix form in the first horizontal direction HD1 and the second horizontal direction HD2 while being spaced apart from the first magnetic tunnel junction structure 110. Also, the second magnetic tunnel junction structure 120 may be arranged alternately with the first magnetic tunnel junction structure 110 in a direction intersecting with the first horizontal direction HD1 and the second horizontal direction HD2, for example, in a third horizontal direction HD3 which is diagonal to the first horizontal direction HD1 and the second horizontal direction HD2. The width of the second magnetic tunnel junction pattern 110 in the first horizontal direction HD1 or the second horizontal direction HD2 (e.g., diameter) will be hereinafter referred to as a second width W2. The second width W2 may be greater than the first width W1.

The third magnetic tunnel junction structure 130 may have a pillar shape. In an embodiment, the third magnetic tunnel junction structure 130 may have an elliptical shape or a shape similar to the elliptical shape in the top view. The third magnetic tunnel junction structure 130 may have a long axis corresponding to a relatively large width, and a short axis corresponding to a relatively small width. The third magnetic tunnel junction structures 130, the long axis of which is parallel to the first horizontal direction HD1 and the short axis of which is parallel to the second horizontal direction HD2, may be arranged in the form of a matrix in the first horizontal direction HD1 and the second horizontal direction HD2 to be spaced apart from the first and second magnetic tunnel junction structures 110 and 120, and the third magnetic tunnel junction structures 130 may be arranged alternately with the first magnetic tunnel junction structures 110 in the first horizontal direction HD1 and may be arranged alternately with the second magnetic tunnel junction structures 120 in the second horizontal direction HD2. The third magnetic tunnel junction structures 130, the long axis of which is parallel to the second horizontal direction HD2 and the short axis of which is parallel to the first horizontal direction HD1, may be arranged in the form of a matrix in the first horizontal direction HD1 and the second horizontal direction HD2 to be spaced apart from the first and second magnetic tunnel junction structures 110 and 120, and the third magnetic tunnel junction structures 130 may be arranged alternately with the second magnetic tunnel junction structure 120 in the first horizontal direction HD1 and may be arranged alternately with the first magnetic tunnel junction structure 110 in the second horizontal direction HD2. The width of the short axis of the third magnetic tunnel junction pattern 110 may be referred to as a third width W3, and the width of the long axis may be referred to as a fourth width W4. The third width W3 may have a value substantially the same as the first width W1, and the fourth width W4 may have a value substantially the same as the second width W2. The meaning of “substantially the same” may include not only cases where two values are identical but also cases where two values are of similar values with a slight difference within a predetermined limit or a certain small range. For example, the third width W3 may have a value of approximately 0.8 to 1.2 times the first width W1, and the fourth width W4 may have a value of approximately 0.8 to 1.2 times the second width W2.

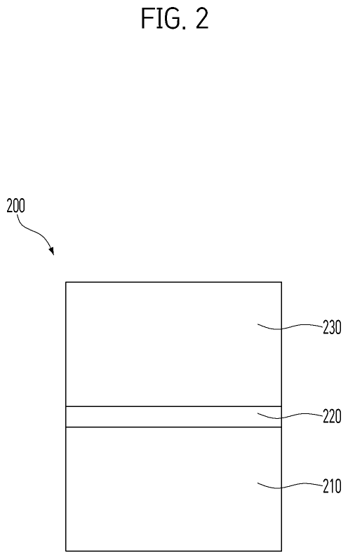

The first magnetic tunnel junction structure 110, the second magnetic tunnel junction structure 120, and the third magnetic tunnel junction structure 130 may have different widths in a plan view, and have the same layer structure and have substantially the same vertical thickness. This is because the first to third magnetic tunnel junction structures 110, 120, and 130 are formed by depositing material layers for forming the first to third magnetic tunnel junction structures 110, 120, and 130 and then etching the material layers in a single patterning process, as will be explained below. The layer structure of the first to third magnetic tunnel junction structures 110, 120, and 130 will be described with reference to FIG. 2 by way of example.

FIG. 2 is a cross-sectional view illustrating a magnetic tunnel junction structure according to an embodiment of the disclosed technology.

Referring to FIG. 2, the magnetic tunnel junction structure 200 may include a stacked structure of a first magnetic pattern 210, a tunnel barrier pattern 220, and a second magnetic pattern 230.

One of the first magnetic pattern 210 and the second magnetic pattern 230 may correspond to a fixed layer having a fixed magnetization direction, and the other of the first magnetic pattern 210 and the second magnetic pattern 230 may correspond to a free layer having a changeable magnetization direction. The fixed layer may be a layer that may be compared to the magnetization direction of the free layer, and the fixed layer may also be referred to as a reference layer. The free layer may be a layer that may store different data according to the magnetization direction, and may also be referred to as a storage layer. Each of the first magnetic pattern 210 and the second magnetic pattern 230 may have a magnetization direction that is substantially parallel to the surface of the layer, for example, the top surface of the layer, or may have a magnetization direction that is substantially perpendicular to the surface of the layer. The tunnel barrier pattern 220 may enable tunneling of electrons between the first magnetic pattern 210 and the second magnetic pattern 230 according to the voltage or current applied to the magnetic tunnel junction structure 200, while physically separating the first magnetic pattern 210 and the second magnetic pattern 230 from each other. Each of the first magnetic pattern 210 and the second magnetic pattern 230 may independently have a single-layer structure or a multi-layer structure including a ferromagnetic material. For example, the first magnetic pattern 210 and the second magnetic pattern 230 may independently include an alloy containing Fe, Ni, or Co as a main component, such as at least one among Fe—Pt alloy, Fe—Pd alloy, Co—Pd alloy, Co—Pt alloy, Fe—Ni—Pt alloy, Co—Fe—Pt alloy, Co—Ni—Pt alloy, and Co—Fe—B alloy, or may include at least one among a stacked structure of Co/Pt and a stacked structure of Co/Pd. The tunnel barrier pattern 220 may have a single-layer structure or a multi-layer structure including a dielectric material. For example, the tunnel barrier pattern 220 may include a dielectric oxide, such as MgO, CaO, SrO, TiO, VO, or NbO.

The magnetic tunnel junction structure 200 may store different data by being controlled to be in different resistance states according to the voltage or current applied through the top and bottom portions of the magnetic tunnel junction structure 200. The resistance state of the magnetic tunnel junction structure 200 may be changed or switched between the different resistance states according to the voltage or current applied through the top and bottom portions of the magnetic tunnel junction structure 200 to provide a reprogrammable memory structure. Therefore, the magnetic tunnel junction structure 200 may function as a memory cell. In some implementations, when the magnetization direction of the free layer, which is one of the first and second magnetic patterns 210 and 230, is changed to be parallel to the magnetization direction of the fixed layer according to the voltage or current applied to the magnetic tunnel junction structure 200, the magnetic tunnel junction structure 200 may have a low resistance state, for example, data “1.” On the other hand, when the magnetization direction of the free layer among the first and second magnetic patterns 210 and 230 is changed to be anti-parallel to the magnetization direction of the fixed layer according to the voltage or current applied to the magnetic tunnel junction structure 200, the magnetic tunnel junction structure 200 may have a high resistance state, for example, data “0.”

In various implementations, the magnetic tunnel junction structure 200 may be structured to include two magnetic patterns 210 and 230 and the tunnel barrier pattern 220 interposed between the two magnetic patterns 210 and 230 and the specific configuration of this multi-layer structure of the magnetic tunnel junction structure 200 may be in various ways for various considerations or applications. For example, the magnetic tunnel junction structure 200 may further include one or more layers to improve characteristics. For example, the magnetic tunnel junction structure 200 may further include one or more fixed layers that are anti-ferromagnetically coupled to the fixed layer among the first and second magnetic patterns 210 and 230 to form a Synthetic Anti-Ferromagnetic structure (SAF) structure. Also, for example, the magnetic tunnel junction structure 200 may further include one or more conductive patterns that are disposed below the first magnetic pattern 210 and/or over the second magnetic pattern 230. This conductive pattern may be referred to as an electrode layer, a hard mask layer, a capping layer, a seed layer depending on its function.

As the magnetic tunnel junction structure 200 has a greater width and/or size in the top view, the amount of the electrical current required to reverse the magnetization direction of the free layer may increase. The increase in the amount of the electrical current required to reverse the magnetization direction of the free layer may mean that data retention characteristics are improved, but the operation speed is slow and the power consumption is high. On the other hand, a decrease in the amount of the electrical current required to reverse the magnetization direction of the free layer may mean that the operation speed is fast and the power consumption is low even though the data retention characteristics may be somewhat compromised or deteriorated. Therefore, when the width of the magnetic tunnel junction structure 200 is relatively large, it may be used for semiconductor devices that require excellent data retention characteristics, such as a flash memory. On the other hand, when the width of the magnetic tunnel junction structure 200 is relatively small, it may be used for semiconductor devices that require low-power high-speed operation, such as a cache memory.

Referring back to FIGS. 1A and 1B which does not show the specific the layer structures of the first to third magnetic tunnel junction structures 110, 120, and 130, in various implementations, each of the first to third magnetic tunnel junction structures 110, 120 and 130 may have the same layer structure as that of the magnetic tunnel junction structure 200 of FIG. 2.

Here, each of the first magnetic tunnel junction structure 110 and the second magnetic tunnel junction structure 120 may function as a memory cell that stores data. Since the first magnetic tunnel junction structure 110 and the second magnetic tunnel junction structure 120 have different widths in the top view, it is possible to realize a semiconductor device including the magnetic tunnel junction structures 110 and 120 of distinctive characteristics at the same time.

Meanwhile, the third magnetic tunnel junction structure 130 may correspond to a dummy structure that is formed as a result of a fabrication process, which will be described later. Unlike the first and second magnetic tunnel junction structures 110 and 120, which are coupled to and controlled by the conductive lines, the third magnetic tunnel junction structure 130 may be surrounded by a dielectric material and may be electrically disconnected from the other constituent elements so that the third magnetic tunnel junction structure 130 is not electrically powered to perform certain operations such as switching between different resistance states and, in this context, is a dummy structure. Even in this case, as the third magnetic tunnel junction structure 130 has an elliptical shape or a shape similar to the elliptical shape in the top view, an in-plane stray magnetic field may be created in the long axis direction of the third magnetic tunnel junction structure 130 due to the shaped-based magnetization. This in-plane stray magnetic field may improve the magnetization reversal speed, that is, the switching speed, of a magnetic tunnel junction structure having a perpendicular magnetization direction that is located adjacent to the third magnetic tunnel junction structure 130 where the in-plane stray magnetic field of the third magnetic tunnel junction structure 130 is present. Therefore, when the first magnetic tunnel junction structure 110 disposed adjacent to the third magnetic tunnel junction structure 130 in the long axis direction of the third magnetic tunnel junction structure 130 includes a magnetic pattern having a perpendicular magnetization direction, the third magnetic tunnel junction structure 130 may further improve the operation speed of the adjacent first magnetic tunnel junction structure 110. On the other hand, the third magnetic tunnel junction structure 130 may not substantially affect the second magnetic tunnel junction structure 120 which is disposed adjacent to the third magnetic tunnel junction structure 130 in the short axis direction.

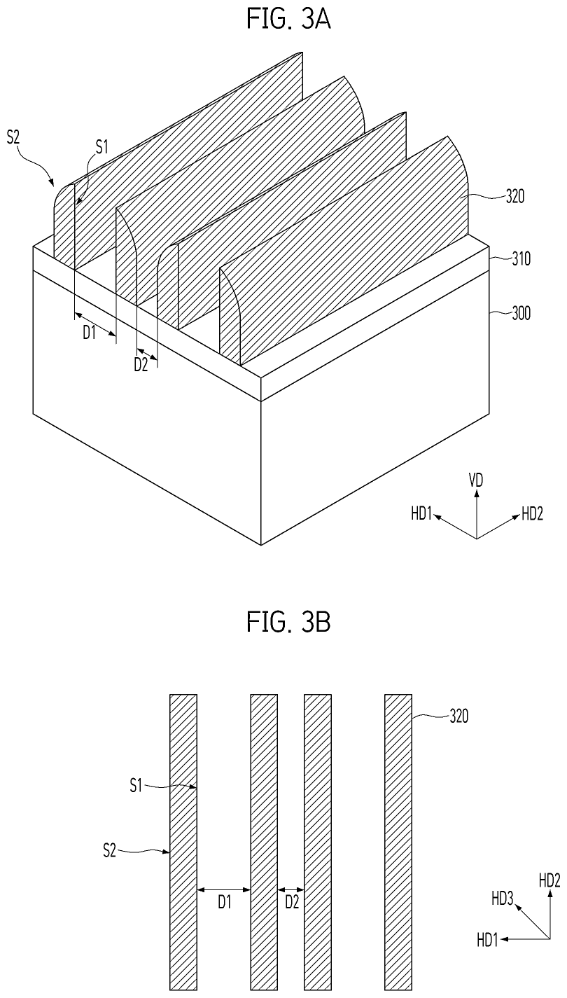

Examples of the method for fabricating a semiconductor device described above will be described below with reference to FIGS. 3A to 7B.

FIGS. 3A to 7B illustrate a method for fabricating a semiconductor device based on an embodiment of the disclosed technology. FIGS. 3A, 4A, 5A, 6A, and 7A are perspective views, and FIGS. 3B, 4B, 5B, 6B, and 7B are top views of FIGS. 3A, 4A, 5A, 6A, and 7A, respectively.

Referring to FIGS. 3A and 3B, a magnetic tunnel junction layer 300 for forming a magnetic tunnel junction structure may be formed over a substrate (not shown) e.g., by a deposition process. The magnetic tunnel junction layer 300 may have a multi-layer structure with a tunnel barrier layer interposed between at least two magnetic layers.

Subsequently, a sacrificial layer 310 may be formed over the magnetic tunnel junction layer 300. The sacrificial layer 310 may be formed of various materials that may be easily removed in the subsequent processes. For example, the sacrificial layer 310 may include at least one of silicon oxide, amorphous carbon, and the like.

Subsequently, a plurality of first spacer patterns 320 may be formed over the sacrificial layer 310 to be spaced apart from each other in the first horizontal direction HD1 and may extend in parallel with each other in the second horizontal direction HD2. The first spacer pattern 320 may include a first side S1 with a flat surface and a second side S2 having at least a curved upper surface. When two first spacer patterns 320 that are arranged to have their first sides S1 facing each other are referred to as a pair of first spacer patterns 320, a plurality of pairs of first spacer patterns 320 may be arranged in the first horizontal direction HD1. In other words, a pair of first spacer patterns 320 may be symmetric with each other in the first horizontal direction HD1. Two first spacer patterns 320 belonging to different pairs and disposed adjacent to each other may be arranged to have their second sides S2 facing each other. Here, when the distance between the two first spacer patterns 320 belonging to one pair and disposed adjacent to each other is referred to as a first distance D1 and the distance between the two first spacer patterns 320 belonging to different pairs and disposed adjacent to each other is referred to as a second distance D2, the first distance D1 may be greater than the second distance D2. The second distance D2 and the first distance D1 may be repeatedly arranged in the first horizontal direction HD1.

This first spacer pattern 320 may be formed through the following process. First, a plurality of line patterns (not shown) may be formed over the sacrificial layer 310 to be spaced apart from each other in the first horizontal direction HD1 and extend in the second horizontal direction HD2. This line pattern may have a line width that is substantially the same as the first distance D1 by overlapping with the area between the two first spacer patterns 320 belonging to a pair and disposed adjacent to each other. Subsequently, first spacer patterns 320 may be formed on both side walls of the line pattern by conformally depositing a material for forming the first spacer pattern 320 on the profile of the process result including the line pattern, and then performing a blanket etching process to expose the top surface of the line pattern and the top surface of the sacrificial layer 310. Subsequently, by removing the line pattern, the process result as illustrated in FIGS. 3A and 3B may be obtained. The first spacer pattern 320 may include a material having a different etch rate from that of the sacrificial layer 310, such as silicon nitride.

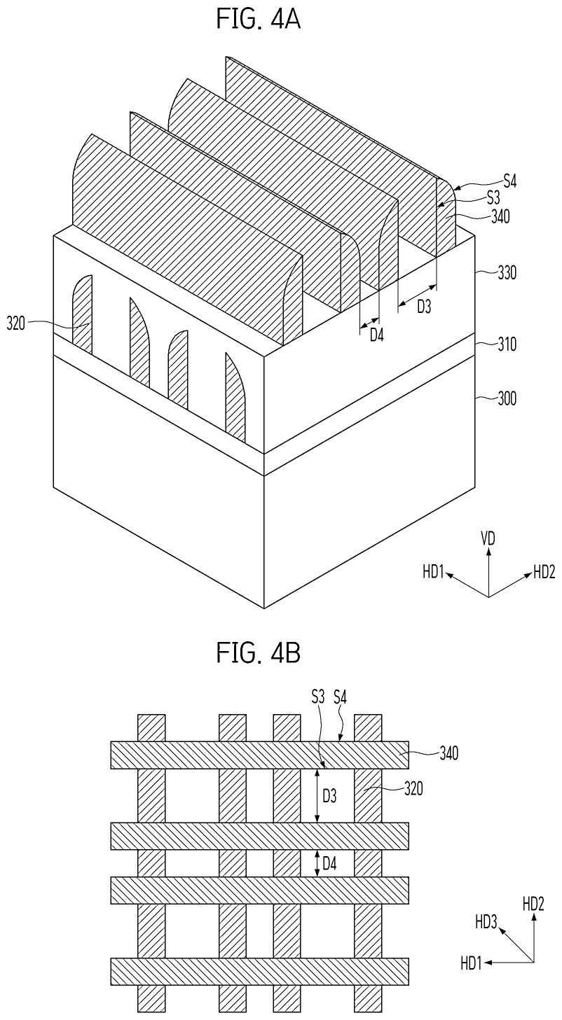

Referring to FIGS. 4A and 4B, a material layer 330 that fills the space between the first spacer patterns 320 may be formed by covering the first spacer patterns 320. The material layer 330 may include a material having a different etch rate from those of the first spacer pattern 320 and the sacrificial layer 310. For example, when the sacrificial layer 310 includes silicon oxide, the material layer 330 may include amorphous carbon. Also, for example, when the sacrificial layer 310 includes amorphous carbon, the material layer 330 may include silicon oxide.

Subsequently, a plurality of second spacer patterns 340 arranged to be spaced apart from each other in the second horizontal direction HD2 and extending in the first horizontal direction HD1 may be formed over the material layer 330. A second spacer pattern 340 may include a first side S3 of a straight-line shape in the second horizontal direction HD2 and a second side S4 having at least a curved top. When two second spacer patterns 340 arranged to have their first sides S3 facing each other are referred to as a pair of the first spacer patterns 340, a plurality of pairs of second spacer patterns 340 may be arranged in the second horizontal direction HD2. Two second spacer patterns 340 belonging to different pairs and disposed adjacent to each other may be arranged to have their second sides S4 facing each other. Here, the distance between the two second spacer patterns 340 belonging to one pair and disposed adjacent to each other may be referred to as a third distance D3, and the distance between the two second spacer patterns 340 belonging to different pairs and disposed adjacent to each other may be referred to as a fourth distance D4, the third distance D3 may be greater than the fourth distance D4. Also, the third distance D3 may be substantially the same as the above-described first distance D1, and the fourth distance D4 may be substantially the same as the above-described second distance D2. The third distance D3 and the fourth distance D4 may be repeatedly arranged in the second horizontal direction HD2. The line width of the second spacer pattern 340 may be substantially the same as the line width of the first spacer pattern 320. The second spacer pattern 340 may include a material having an etch rate which is different from those of the sacrificial layer 310 and the material layer 330. For example, the second spacer pattern 340 may include the same material as the first spacer pattern 320, such as silicon nitride. In some implementations, the process of forming the second spacer pattern 340 may be substantially the same as the process of forming the first spacer pattern 320 except for the direction of the line pattern.

As a result of this process, a large square area, a small square area, and a rectangular area in the plan view may be defined by the first spacer pattern 320 and the second spacer pattern 340. In some implementations, a large square area may be defined by a pair of first spacer patterns 320 and a pair of second spacer patterns 340 crossing the pair of the first spacer patterns 320. A small square area may be defined by two first spacer patterns 320 belonging to different pairs and disposed adjacent to each other, and two second spacer patterns 340 belonging to different pairs, disposed adjacent to each other and intersecting with the two first spacer patterns 320. A rectangular area whose width in the first horizontal direction HD1 is greater than the width in the second horizontal direction HD2 may be defined by a pair of first spacer patterns 320 and two second spacer patterns 340 belonging to different pairs, disposed adjacent to each other, and intersecting with the pair of the first spacer patterns 320. A rectangular area whose width in the first horizontal direction HD1 is smaller than the width in the second horizontal direction HD2 may be defined by two first spacer patterns 320 belonging to different pairs, disposed adjacent to each other, and a pair of second spacer patterns 340 intersect with the two first spacer patterns 320.

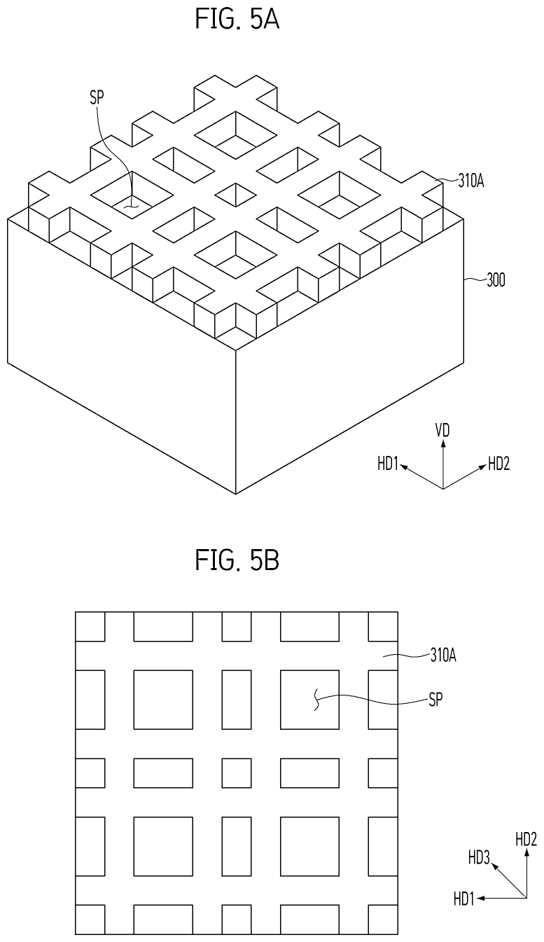

Referring to FIGS. 5A and 5B, a sacrificial layer pattern 310A may be formed by etching the material layer 330 by using the second spacer pattern 340 as an etch barrier, and then etching the sacrificial layer 310 that is exposed by etching the material layer 330.

Here, since the first spacer pattern 320 and the second spacer pattern 340 are maintained while the material layer 330 is etched, as a result of etching the material layer 330, the remaining portion of the sacrificial layer 310 excluding the portion overlapping with the first spacer pattern 320 and the second spacer pattern 340 may be revealed. In other words, as a result of etching the material layer 330, portions of the sacrificial layer 310 corresponding to the above-described large square area, small square area, and rectangular areas may be revealed. Accordingly, the sacrificial layer pattern 310A may have a mesh shape including the space SP that is formed by etching the portions corresponding to the above-described large square area, small square area, and rectangular areas.

In the process of forming the sacrificial layer pattern 310A, or through a separate removal process, the second spacer pattern 340, the etched material layer 330, and the first spacer pattern 320 may be removed.

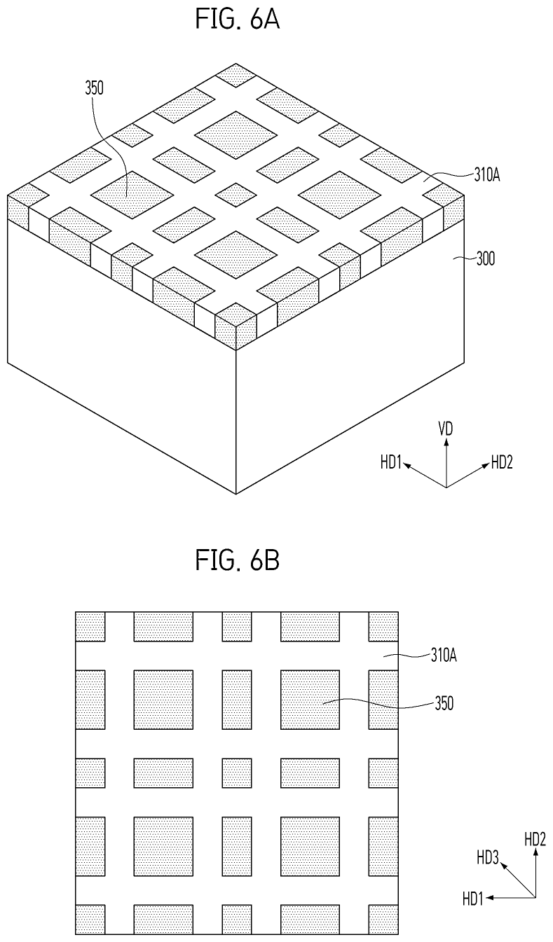

Referring to FIGS. 6A and 6B, a hard mask pattern 350 may be formed to fill the space SP that is defined by the sacrificial layer pattern 310A.

The hard mask pattern 350 may include a material having a different etch rate from that of the sacrificial layer pattern 310A. For example, the hard mask pattern 350 may include a conductive material, such as a metal, a metal compound, or an alloy, or a dielectric material, such as silicon nitride. The hard mask pattern 350 may be formed by depositing a material for forming the hard mask pattern 350 over the sacrificial layer pattern 310A to have a thickness that sufficiently fills the space SP, and performing a planarization process or an etch-back process to expose the top surface of the sacrificial layer pattern 310A.

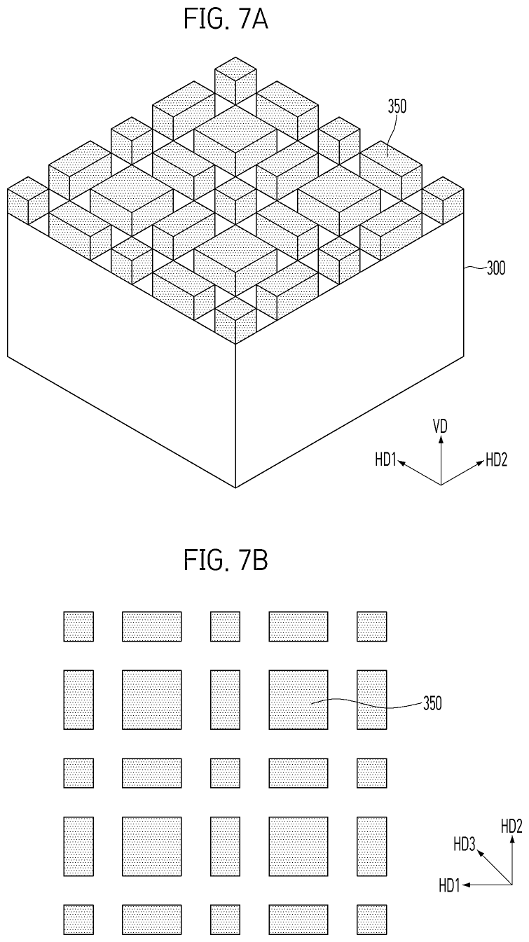

Referring to FIGS. 7A and 7B, the sacrificial layer pattern 310A may be removed. As a result, the hard mask pattern 350 may exist over the magnetic tunnel junction layer 300. The hard mask pattern 350 may have at least one of a large square shape, a small square shape, or a rectangular shape.

When the magnetic tunnel junction layer 350 is etched by using the hard mask pattern 350, magnetic tunnel junction structures whose shape and arrangement are substantially the same as those of the first to third magnetic tunnel junction structures 110, 120, and 130 described in FIGS. 1A and 1B may be obtained. A portion of the magnetic tunnel junction layer 300 that is etched by using the hard mask pattern 350 of a small square shape may form a magnetic tunnel junction structure which is the same as or similar to the first magnetic tunnel junction structure 110, and a portion of the magnetic tunnel junction layer 300 that is etched by using the hard mask pattern 350 of a large square shape may form a magnetic tunnel junction structure that is the same as or similar to the second magnetic tunnel bonding structure 120, and a portion of the magnetic tunnel junction layer 300 that is etched by using the hard mask pattern 350 of a rectangular shape may form a magnetic tunnel junction structure that is the same as or similar to the third magnetic tunnel bonding structure 130. Even though the hard mask pattern 350 has a square shape or a rectangular shape, the corners of the square or rectangular shape may be rounded in the process of etching the magnetic tunnel bonding layer 300 to obtain a magnetic tunnel junction structure of a circular shape, an elliptical shape, or a shape similar to these shapes.

In this way, it is possible to form magnetic tunnel junction structures of different widths through a process of forming a single magnetic tunnel junction layer 300 and a process of patterning the single magnetic tunnel junction layer 300, that is, a process of etching the magnetic tunnel junction layer 300 using the hard mask pattern 350. Therefore, the process may be simplified, and the process costs may be reduced.

Also, the first distance D1 and/or the third distance D3 may be easily controlled by adjusting the line widths of the line pattern for forming the first spacer pattern 320 and/or the second spacer pattern 340. The second distance D2 and/or the fourth distance D4 may be easily controlled by adjusting the line widths of the first spacer pattern 320 and/or the second spacer pattern 340. This may mean that the width and/or size of the hard mask pattern 350 in a top view may be easily adjusted. As a result, magnetic tunnel junction structures of desired widths may be obtained through a relatively simple process.

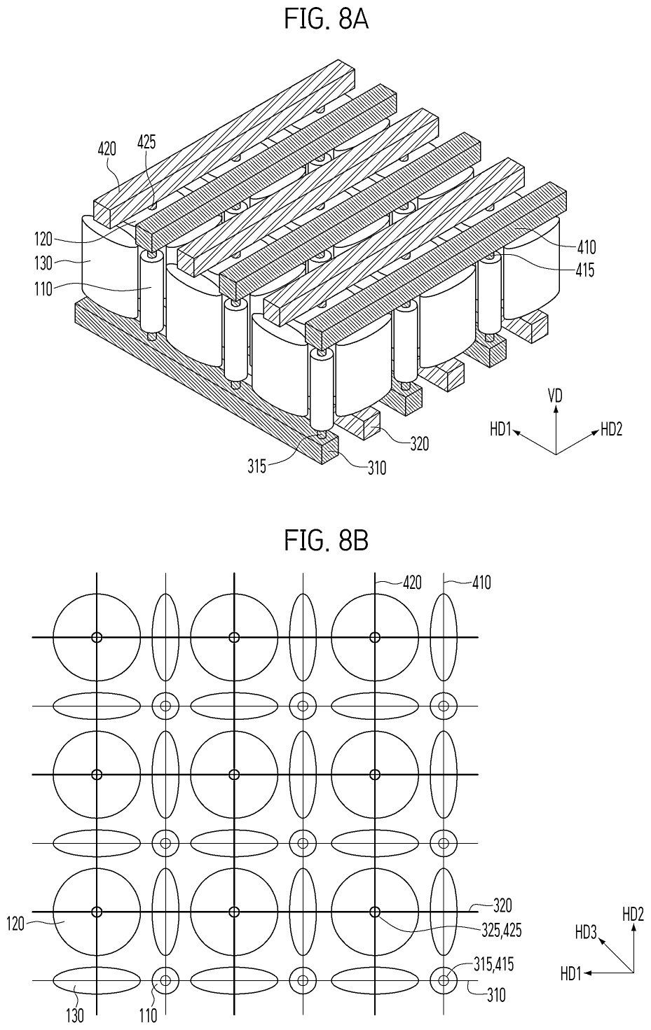

In some implementations, in the semiconductor device of FIGS. 1A and 1B, since the first magnetic tunnel junction structure 110 performs a switching operation in which the resistance is changed according to the voltage or current applied through the top and bottom portions of the first magnetic tunnel junction structure 110, it may be required to form conductive lines that are respectively coupled to the top and bottom portions of the first magnetic tunnel junction structure 110 to transfer a voltage or current to the first magnetic tunnel junction structure 110. Similarly, since the second magnetic tunnel junction structure 120 performs a switching operation in which the resistance is changed according to the voltage or current applied through the top and bottom portions of the second magnetic tunnel junction structure 120, it may be required to form conductive lines that are respectively coupled to the top and bottom portions of the second magnetic tunnel junction structure 120 to transfer the voltage or current to the second magnetic tunnel junction structure 120. The third magnetic tunnel junction structure 130 may be a dummy and it may not require connection to a conductive line. As to the semiconductor device including the first and second magnetic tunnel junction structures 110 and 120 and the conductive lines coupled to the first and second magnetic tunnel junction structures 110 and 120 will be exemplarily described below with reference to FIGS. 8A and 8B.

FIGS. 8A and 8B illustrate a semiconductor device based on another embodiment of the disclosed technology. FIG. 8A is a perspective view, and FIG. 8B is a top view of FIG. 8A. For the sake of convenience in description, in FIG. 8B, a conductive line is represented by a line. Parts that are substantially the same as those of the semiconductor device of FIGS. 1A and 1B described above will be denoted by the same reference numerals and detailed description on them will be omitted.

Referring to FIGS. 8A and 8B, the semiconductor device based on an embodiment of the disclosed technology may include first to third magnetic tunnel junction structures 110, 120, and 130, a first lower conductive line 310 and a second lower conductive line 320 disposed below the first to third magnetic tunnel junction structures 110, 120, and 130, and a first upper conductive line 410 and a second upper conductive line 420 disposed over the first to third magnetic tunnel junction structures 110, 120, and 130.

The first lower conductive line 310 may extend in the first horizontal direction HD1 while overlapping with and electrically connected to the first magnetic tunnel junction structures 110 that are arranged in the first horizontal direction HD1. The first lower conductive line 310 may be coupled to the first magnetic tunnel junction structure 110 through the first lower contact 315 which is interposed between the first lower conductive line 310 and the first magnetic tunnel junction structure 110. The first lower contact 315 may have a pillar shape, and the first lower contacts 315 may overlap with and be coupled to the first magnetic tunnel junction structures 110, respectively.

The first upper conductive line 410 may extend in the second horizontal direction HD2 while overlapping with and electrically connected to the first magnetic tunnel junction structures 110 that are arranged in the second horizontal direction HD2. The first upper conductive line 410 may be coupled to the first magnetic tunnel junction structure 110 through a first upper contact 415 which is interposed between the first upper conductive line 410 and the first magnetic tunnel junction structure 110. The first upper contact 415 may have a pillar shape, and the first upper contacts 415 may overlap with and be coupled to the first magnetic tunnel junction structures 110, respectively.

The first magnetic tunnel junction structure 110 may overlap with the intersection area between the first lower conductive line 310 and the first upper conductive line 410, and the first magnetic tunnel junction structure 110 may be activated by the voltage or current transferred through the first lower conductive line 310 and the first upper conductive line 410. By activating one among the first lower conductive lines 310 and one among the first upper conductive lines 410, the first magnetic tunnel junction structure 110 coupled to them may be selected and activated.

The second lower conductive line 320 may extend in the first horizontal direction HD1 while overlapping with and being electrically connected to the second magnetic tunnel junction structures 120 that are arranged in the first horizontal direction HD1. The second lower conductive line 320 may be coupled to the second magnetic tunnel junction structure 120 through the second lower contact 325 which is interposed between the second lower conductive line 320 and the second magnetic tunnel junction structure 120. The second lower contact 325 may have a pillar shape, and the second lower contacts 325 may overlap with and be coupled to the second magnetic tunnel junction structures 120, respectively. In the second horizontal direction HD2, the second lower conductive lines 320 may be arranged alternately with the first lower conductive lines 310 while being spaced apart from the first lower conductive lines 310.

The second upper conductive line 420 may extend in the second horizontal direction HD2 while overlapping with and electrically connected to the second magnetic tunnel junction structures 120 that are arranged in the second horizontal direction HD2. The second upper conductive line 420 may be coupled to the second magnetic tunnel junction structure 120 through the second upper contact 425 which is interposed between the second upper conductive line 420 and the second magnetic tunnel junction structure 120. The second upper contact 425 may have a pillar shape, and the second upper contacts 425 may overlap with and be coupled to the second magnetic tunnel junction structures 120, respectively. In the first horizontal direction HD1, the second upper conductive lines 420 may be arranged alternately with the first upper conductive lines 410 while being spaced apart from the first upper conductive lines 410.

The second magnetic tunnel junction structure 120 may overlap with the intersection area between the second lower conductive line 320 and the second upper conductive line 420, and the second magnetic tunnel junction structure 120 may be activated by the voltage or current transferred through the second lower conductive line 320 and the second upper conductive line 420. By activating one among the second lower conductive lines 320 and one among the second upper conductive lines 420, the second magnetic tunnel junction structure 120 coupled to them may be selected and activated.

In an embodiment, in the vertical direction VD, the first lower conductive line 310 and the second lower conductive line 320 may be disposed at the same level, and the second upper conductive line 410 and the second upper conductive line 420 may be disposed at the same level. However, the disclosed technology is not limited to this example, and the first lower conductive line 310 and the second lower conductive line 320 may be disposed below the first to third magnetic tunnel junction structures 110, 120, and 130 at different levels in the vertical direction VD. In this case, an electrical short circuit between the first lower conductive line 310 and the second lower conductive line 320 may be prevented and/or reduced. Also, the first upper conductive line 410 and the second upper conductive line 420 may be disposed at different levels in the vertical direction VD over the first to third magnetic tunnel junction structures 110, 120, and 130. In this case, an electrical short circuit between the first upper conductive line 410 and the second upper conductive line 420 may be prevented and/or reduced.

Also, in an embodiment, the first and second lower conductive lines 310 and 320 may extend in the first horizontal direction HD1, and the first and second upper conductive lines 410 and 420 may extend in the second horizontal direction HD2. However, the disclosed technology is not limited to this example, and the first and second lower conductive lines 310 and 320 may extend in the second horizontal direction HD2, and the first and second upper conductive lines 410 and 420 may extend in the first horizontal direction HD1.

The space between the first lower conductive line 310 and the second lower conductive line 320, the space between the first lower contact 315 and the second lower contact 325, the space between the first to third magnetic tunnel junction structures 110, 120, and 130, the space between the first upper conductive line 410 and the second upper conductive line 420, and the space between the first upper contact 415 and the second upper contact 425 may be filled with a dielectric material. Accordingly, the third magnetic tunnel junction structure 130 may be surrounded by this dielectric material and may be in a floating state that it is not electrically connected to the other constituent elements.

Each of the first and second lower conductive lines 310 and 320, the first and second lower contacts 315 and 325, the first and second upper conductive lines 410 and 420, and the first and second upper contacts 415 and 425 may independently include diverse conductive materials, for example, a metal such as platinum (Pt), tungsten (W), aluminum (Al), copper (Cu), tantalum (Ta) and the like, a metal nitride such as titanium nitride (TiN), tantalum nitride (TaN) and the like, or a combination thereof, and may have a single-layer structure or a multi-layer structure.

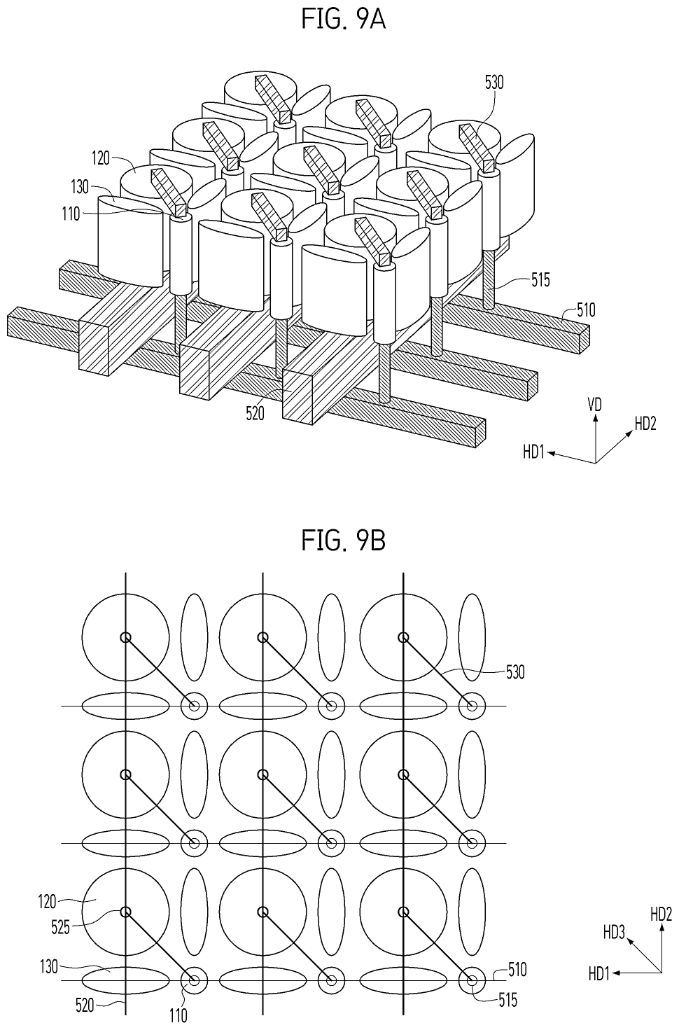

In the above-described embodiment, each of the first magnetic tunnel junction structure 110 and the second magnetic tunnel junction structure 120 may function as one memory cell. However, in another embodiment, the first magnetic tunnel junction structure 110 and the second magnetic tunnel junction structure 120 may be serially coupled to form one memory cell. In this case, the memory cell may function as a multi-bit memory cell capable of storing at least 2 bits of data, as will be discussed with reference to FIGS. 9A and 9B.

FIGS. 9A and 9B illustrate a semiconductor device based on another embodiment of the disclosed technology.

Referring to FIGS. 9A and 9B, the semiconductor device based on embodiment of the disclosed technology may include the first to third magnetic tunnel junction structures 110, 120, and 130, a first conductive line 510 and a second conductive line 520 disposed below the first to third magnetic tunnel junction structures 110, 120, and 130, and a connection pattern 530 disposed over the first to third magnetic tunnel junction structures 110, 120, and 130.

The first conductive line 510 may extend in the first horizontal direction HD1 while overlapping with and electrically connected to the first magnetic tunnel junction structures 110 that are arranged in the first horizontal direction HD1. The first conductive line 510 may be coupled to the first magnetic tunnel junction structure 110 through a first contact 515 interposed between the first conductive line 510 and the first magnetic tunnel junction structure 110. The first contact 515 may have a pillar shape, and the first contacts 515 may overlap with and be coupled to the first magnetic tunnel junction structures 110, respectively.

The second conductive line 520 may extend in the second horizontal direction HD2 while overlapping with and electrically connected to the second magnetic tunnel junction structures 120 that are arranged in the second horizontal direction HD2. The second conductive line 520 may be coupled to the second magnetic tunnel junction structure 120 through a second contact 525 which is interposed between the second conductive line 520 and the second magnetic tunnel junction structure 120. The second contact 525 may have a pillar shape, and the second contacts 525 may overlap with and be coupled to the second magnetic tunnel junction structures 120, respectively.

Since the first conductive line 510 and the second conductive line 520 extend in directions that intersect with each other, they may be disposed at diverse levels in the vertical direction VD. This is because an electrical short circuit may occur when the first conductive line 510 and the second conductive line 520 are disposed at the same level in the vertical direction VD. In an embodiment, the first conductive line 510 may be disposed below the second conductive line 520. To this end, the thickness of the first contact 515 may be greater than the thickness of the second contact 525. However, the disclosed technology is not limited to this implementation, and the first conductive line 510 may be disposed over the second conductive line 520.

The connection pattern 530 may connect one first magnetic tunnel junction structure 110 and one second magnetic tunnel junction structure 120 that are disposed adjacent to each other in the third horizontal direction HD3. The first magnetic tunnel junction structure 110 and the second magnetic tunnel junction structure 120 that are coupled by one connection pattern 530 may be referred to as a pair of the first and second magnetic tunnel junction structures 110 and 120. A plurality of pairs of the first and second magnetic tunnel junction structures 110 and 120 may be repeatedly arranged in the third horizontal direction HD3. According to the embodiment, the connection pattern 530 may directly contact the top surfaces of the first and second magnetic tunnel junction structures 110 and 120. However, the disclosed technology is not limited thereto, and the connection pattern 530 may be coupled to the first and second magnetic tunnel junction structures 110 and 120 through the contact interposed between the connection pattern 530 and the first and second magnetic tunnel junction structures 110 and 120.

The pair of the first and second magnetic tunnel junction structures 110 and 120 may be activated by the voltage or current transferred through the first conductive line 510 and the second conductive line 520. By activating one among the first conductive lines 510 and one among the second conductive lines 520, a pair of the first and second magnetic tunnel junction structures 110 and 120 coupled thereto may be selected and activated. For example, when a pair of the first and second magnetic tunnel junction structures 110 and 120 is selected, one flow passing through one first conductive line 510, the first contact 515 coupled thereto, the first magnetic tunnel junction structure 110 coupled thereto, the connection pattern 530 coupled thereto, the second magnetic tunnel junction structure 120 coupled thereto, the second contact 525 coupled thereto, and the second conductive line 520 coupled thereto may be formed. The first magnetic tunnel junction structure 110 and the second magnetic tunnel junction structure 120 may be serially coupled through the connection pattern 530.

A pair of the first and second magnetic tunnel junction structures 110 and 120 may form one memory cell. Here, according to the voltage or current transferred to the pair of the first and second magnetic tunnel junction structures 110 and 120 through the first and second conductive lines 510 and 520, the pair of the first and second magnetic tunnel junction structures 110 and 120 may be capable of storing 2-bit data. For example, when each of the first and second magnetic tunnel junction structures 110 and 120 has a high resistance state, data ‘00’ may be stored. Alternatively, when the first magnetic tunnel junction structure 110 has a high resistance state and the second magnetic tunnel junction structure 120 has a low resistance state, data ‘01’ may be stored. Alternatively, when the first magnetic tunnel junction structure 110 has a low resistance state and the second magnetic tunnel junction structure 120 has a high resistance state, data ‘10’ may be stored. Alternatively, when each of the first and second magnetic tunnel junction structures 110 and 120 has a low resistance state, data ‘11’ may be stored. In this way, it is possible to realize multi-bit memory cells.

Each of the first and second conductive lines 510 and 520, the first and second contacts 515 and 525, and the connection pattern 530 may include independently diverse conductive materials, for example, a metal such as platinum (Pt), tungsten (W), aluminum (AI), copper (Cu), tantalum (Ta) and the like, a metal nitride such as titanium nitride (TiN), tantalum nitride (TaN) and the like, or a combination thereof, and has a single-layer structure or a multi-layer structure.

In an embodiment of the disclosed technology, the first and second conductive lines 510 and 520 may be disposed below the first to third magnetic tunnel junction structures 110, 120, and 130 and the connection pattern 530 is disposed over the first to third magnetic tunnel junction structures 110, 120, and 130, but the disclosed technology is not limited thereto. In another embodiment, the first and second conductive lines 510 and 520 may be disposed over the first to third magnetic tunnel junction structures 110, 120, and 130, and the connection pattern 530 may be disposed below the first to third magnetic tunnel junction structures 110, 120, and 130. In other words, in the vertical direction VD, the first and second conductive lines 510, 520 and the connection pattern 530 may be disposed on the opposite sides from each other with the first to third magnetic tunnel junction structures 110, 120, and 130 interposed between them.

In an embodiment of the disclosed technology, the first conductive line 510 may extend in the first horizontal direction HD1 and the second conductive line 520 extends in the second horizontal direction HD2, but the disclosed technology is not limited to this. In another embodiment, the first conductive line 510 may extend in the second horizontal direction HD2, and the second conductive line 520 may extend in the first horizontal direction HD1.

In this way, a semiconductor device based on some embodiments may include magnetic tunnel junction structures of varied sizes that may be easily formed, and the semiconductor device may be formed by performing the method discussed above.

Only a few embodiments and examples are described. Enhancements and variations of the disclosed embodiments and other embodiments can be made based on what is described and illustrated in this patent document.

What is claimed is:

1. A semiconductor device, comprising:
a plurality of first magnetic tunnel junction structures arranged in a first direction and a second direction intersecting with each other and having a first width in the first direction;
a plurality of second magnetic tunnel junction structures arranged in the first direction and the second direction and arranged alternately with the first magnetic tunnel junction structures in a third direction intersecting with the first and second directions, and having a second width in the first direction, wherein the second width is greater than the first width; and
a plurality of third magnetic tunnel junction structures, a first group of third magnetic tunnel junction structures having a third width in the first direction and a fourth width in the second direction, arranged alternately with the first magnetic tunnel junction structures in the first direction, and arranged alternately with the second magnetic tunnel junction structures in the second direction, a second group of third magnetic tunnel junction structures having a fifth width in the second direction and a sixth width in the first direction, arranged alternately with the second magnetic tunnel junction structures in the first direction, and arranged alternately with the first magnetic tunnel junction structures in the second direction, wherein the third width is greater than the fourth width, and the fifth width is greater than the sixth width.

2. The semiconductor device of claim 1, wherein the first to third magnetic tunnel junction structures have a same layer structure and a same thickness.

3. The semiconductor device of claim 1, wherein the fourth and sixth widths of the plurality of third magnetic tunnel junction structures are equal to the first width, and
the third and fifth widths of the plurality of third magnetic tunnel junction structures are equal to the second width.

4. The semiconductor device of claim 1, wherein shapes of the plurality of first magnetic tunnel junction structures and the plurality of second magnetic tunnel junction structures in a plan view are circular shapes, and
shapes of the plurality of third magnetic tunnel junction structures in the plan view are elliptical shapes.

5. The semiconductor device of claim 1, wherein:
the plurality of first magnetic tunnel junction structures includes a magnetic pattern having a perpendicular magnetization direction, the perpendicular magnetization direction being reversed by a voltage or current applied through both ends of the plurality of first magnetic tunnel junction structures;
the plurality of third magnetic tunnel junction structures has a floating state; and
an in-plane stray field created in a direction of the third width and a direction of the fifth width of the plurality of third magnetic tunnel junction structures increases a reversal speed of the perpendicular magnetization direction.

6. The semiconductor device of claim 1,
wherein each of the first and second magnetic tunnel junction structures has a resistance state that varies depending on a voltage or current applied through both ends of each of the first and second magnetic tunnel junction structures,
wherein the plurality of third magnetic tunnel junction structures is in a floating state.

7. The semiconductor device of claim 1, further comprising:
a first lower conductive line electrically connecting the first magnetic tunnel junction structures that are arranged in one of the first direction and the second direction below the first magnetic tunnel junction structures;
a first upper conductive line electrically connecting the first magnetic tunnel junction structures that are arranged in the other of the first direction and the second direction over the first magnetic tunnel junction structures;
a second lower conductive line electrically connecting the second magnetic tunnel junction structures that are arranged in the one of the first direction and the second direction below the second magnetic tunnel junction structures; and
a second upper conductive line electrically connecting the second magnetic tunnel junction structures that are arranged in the other of the first direction and the second direction over the second magnetic tunnel junction structures.

8. The semiconductor device of claim 1, wherein:
the first and second magnetic tunnel junction structures are serially coupled to form a pair of first and second magnetic tunnel junction structures, and
a resistance state of the pair of the first and second magnetic tunnel junction structures is varied by a voltage or current applied through both ends of the pair of the first and second magnetic tunnel junction structures,
the plurality of third magnetic tunnel junction structures is in a floating state.

9. The semiconductor device of claim 1, further comprising:
a connection pattern disposed over or below the first and second magnetic tunnel junction structures and connecting the first and second magnetic tunnel junction structures that are disposed adjacent to each other in the third direction.

10. The semiconductor device of claim 9, further comprising:
a first conductive line disposed on an opposite side of the connection pattern with the first and second magnetic tunnel junction structures interposed therebetween in a vertical direction, and electrically connecting the plurality of first magnetic tunnel junction structures that are arranged in one of the first direction and the second direction; and
a second conductive line disposed on an opposite side of the connection pattern with the first and second magnetic tunnel junction structures interposed therebetween in the vertical direction, and electrically connecting the second magnetic tunnel junction structures that are arranged in the other of the first direction and the second direction.

11. The semiconductor device of claim 10, wherein in the vertical direction, the first conductive line and the second conductive line are disposed at different levels.

12. The semiconductor device of claim 1, wherein an amount of current required to reverse a magnetization direction of the plurality of first magnetic tunnel junction structures is smaller than an amount of current required to reverse a magnetization direction of the plurality of second magnetic tunnel junction structure.

13. The semiconductor device of claim 1, wherein:
the first and second magnetic tunnel junction structures are coupled to one or more conductive lines, and
the third magnetic tunnel junction structure is surrounded by a dielectric material.

14. The semiconductor device of claim 1, wherein each of the first to third magnetic tunnel junction structures includes two magnetic patterns, and a tunnel barrier pattern interposed between the two magnetic patterns.

15. The semiconductor device of claim 1, wherein the plurality of third magnetic tunnel junction structures are dummy structures.

16. A method for fabricating a semiconductor device, comprising:
forming a magnetic tunnel junction layer over a substrate;
forming a sacrificial layer over the magnetic tunnel junction layer;
forming a plurality of first spacer patterns extending in a second direction and having different intervals from each other in a first direction over the sacrificial layer;
forming a material layer that covers the first spacer pattern;
forming a plurality of second spacer patterns extending in the first direction and having different intervals from each other in the second direction over the material layer;
etching the material layer by using the second spacer pattern as an etch mask while maintaining the first spacer pattern to expose a portion of the sacrificial layer that does not overlap with the first and second spacer patterns;
forming a space by etching the exposed portion of the sacrificial layer;
forming a hard mask pattern to fill the space;
removing the sacrificial layer; and
etching the magnetic tunnel junction layer by using the hard mask pattern as an etch barrier to form a plurality of magnetic tunnel junction structures having different widths.

17. The method of claim 16, wherein the first spacer pattern and the second spacer pattern include a same material.

18. The method of claim 16, wherein:
the different intervals of the first spacer patterns include first intervals and second intervals smaller than the first intervals, the first intervals and the second intervals being alternately arranged in the first direction, and
the different intervals of the second spacer patterns include third intervals and fourth intervals smaller than the third intervals, the third intervals and the fourth intervals being alternately arranged in the second direction.

19. The method of claim 18, wherein:
the first intervals are equal to the third intervals, and
the second intervals are equal to the fourth intervals.

20. The method of claim 16, wherein a line width of the first spacer pattern is equal to a line width of the second spacer pattern.
